(19) United States
(12) Patent Application Publication
(10) Pub. No.: US 2021/0168955 A1
(43) Pub. Date: Jun. 3, 2021

(54) DISPLAY DEVICE AND DISPLAY DEVICE SEPARATION SYSTEM COMPRISING SAME

(71) Applicant: LG ELECTRONICS INC., Seoul (KR)

(72) Inventors: Kukyoul JEON, Seoul (KR); Joonsub BAE, Seoul (KR)

(73) Assignee: LG ELECTRONICS INC., Seoul (KR)

(21) Appl. No.: 17/047,270

(22) PCT Filed: Jan. 30, 2019
(86) PCT No.: PCT/KR2019/001279

§ 371 Date: Oct. 13, 2020

(30) Foreign Application Priority Data
Apr. 13, 2018 (KR) 10-2018-0043080

(51) Int. Cl. H05K 5/03; H01L 51/52; H05K 5/00; H05K 7/20; B26D 3/28

(52) U.S. Cl. CPC H05K 5/03; H01L 51/5237; H01L 27/3244; H05K 7/20963; B26D 3/28; H05K 5/0017

(57) ABSTRACT

A display device separation system according to an embodiment of the present disclosure can include a display panel, a cover module covering the rear of the display panel and having an opening, an adhesive member located between the display panel and the cover module to bond the display panel to the cover module, a wire configured to cut the adhesive member so that the display panel and the cover module are separated, and an electromotive jig configured to wind the wire. In a state in which the wire is located between the display panel and the cover module along the circumference of the display panel, passes through the opening, and is connected to the electromotive jig, the adhesive member is cut while the wire is wound around the electromotive jig by the rotation of the electromotive jig.

### TECHNICAL FIELD

The present disclosure relates to a display device and a display device separation system including the same, and more particularly, to a display device, in which a heat dissipation sheet is disposed behind a display panel, and a display device separation system including the same.

### BACKGROUND ART

Examples of display devices may include liquid crystal display device (LCD), field emission display (FED), plasma display panel (PDP), and electroluminescence device.

As an example of the electroluminescence device, an active matrix organic light-emitting display device using an organic light-emitting diode (OLED) is commercially available. Since the organic light-emitting display device is a self-luminous device, the organic light-emitting display device has no backlight and has advantages in response time and viewing angle, as compared with the LCD, and thus is attracting attention as a next-generation display.

The display device includes a display module, and the display module includes a display panel on which an image is displayed, and a cover module covering the outer circumference and the rear surface of the display panel. In more detail, a process of manufacturing the display device includes a process of mounting the display panel to the cover module by attaching the display panel to a heat dissipation plate provided inside the cover module. In order to implement an ultra-slim display device, the display panel and the heat dissipation plate are attached by a double-sided tape.

However, in the conventional display device, it is difficult to separate the display panel and the cover module. In more detail, when external tools are inserted between the cover module and the display panel so as to cut the double-sided tape, a crack occurs in the panel, making it impossible to repair a single product for service.

Therefore, even when a problem occurs only in one of the display panel and the cover module, the entire display module needs to be replaced. Thus, there is a problem in that the service cost is excessive.

### DISCLOSURE

### Technical Problem

The problem to be solved by the present disclosure is to provide a display device, in which a display panel and a cover module are easily separated, and a display device separation system including the same.

### Technical Solution

According to an embodiment of the present disclosure, a display device includes a display panel, a cover module covering a rear surface of the display panel, and an adhesive member configured to bond the cover module to the display panel, wherein the adhesive member includes a first adhesive layer attached to the rear surface of the display panel, a first film attached to the first adhesive layer, an auxiliary adhesive layer attached to the first film, a base layer attached to the auxiliary adhesive layer, a second film attached to the base layer, and a second adhesive layer having one side attached to the second film and the other side attached to the cover module.

The cover module may include a cover body located behind the display panel, and a cover circumference portion protruding forward from a circumference of the cover body, surrounding an outer circumference of the display panel, and spaced apart from the outer circumference of the display panel to define a predetermined gap.

The cover module may further include a heat dissipation plate disposed between the cover body and the display panel, and the second adhesive layer may be attached to the heat dissipation plate.

The base layer may be configured to be cut by a wire entered between the display panel and the heat dissipation panel through the gap.

The adhesive member may be provided in plurality. A length corresponding to a thickness of the adhesive member may be shorter than a length corresponding to a minimum distance between one adhesive member and another adhesive member adjacent to the one adhesive member.

The base layer may be located between the first adhesive layer and the second adhesive layer and may have a thickness greater than that of each of the first adhesive layer and the second adhesive layer.

The display device may further include an electrical component provided on the cover body and having an opening communicating with a lower space of the heat dissipation plate.

The opening may be located in a central portion of the cover body with respect to a left-and-right direction.

A material of the base layer may be polyurethane foam.

A material of the first film may be different from a material of the second film.

The display device may further include an auxiliary adhesive member configured to bond the display panel to the cover body, and the opening may be located above the auxiliary adhesive member.

A burr formed around the heat dissipation plate may face the cover body.

An edge of the opening may be formed to be round.

According to an embodiment of the present disclosure, a display device separation system includes a display panel, a cover module covering a rear surface of the display panel and having an opening, an adhesive member located between the display panel and the cover module to bond the display panel to the cover module, a wire configured to cut the adhesive member so that the display panel and the cover module are separated, and an electromotive jig configured to wind the wire, wherein, in a state in which the wire is located between the display panel and the cover module along the circumference of the display panel, passes through the opening, and is connected to the electromotive jig, the adhesive member is cut while the wire is wound around the electromotive jig by the rotation of the electromotive jig.

The display device separation system may further include a guide jig having a through hole through which the wire passes, the guide jig being seated on the rear surface of the cover module, and the through hole may correspond to the opening.

The display device separation system may further include a fixing portion to which one end of the wire is fixed, and the other end of the wire may be connected to the electromotive jig.

The cover module may include a cover body located behind the display panel, and a cover circumference portion protruding forward from a circumference of the cover body, surrounding an outer circumference of the display panel, and spaced apart from the outer circumference of the display panel to define a predetermined gap. The wire may be inserted between the display panel and the cover body through the gap.

The cover module may further include a heat dissipation plate disposed between the cover body and the display panel and having a front surface to which the adhesive member is attached. The wire may penetrate between the display panel and the heat dissipation plate and may cut the adhesive member.

A thickness of the wire may be less than a thickness of the adhesive member.

The opening may be located in a central portion of the cover module with respect to a left-and-right direction, and the guide jig may be seated in a central portion of the rear surface of the cover module so as to correspond to the opening.

### Advantageous Effects

According to a preferred embodiment of the present disclosure, since an adhesive member is cut by a wire, a display panel and a heat dissipation plate can be easily separated. Therefore, when an abnormality occurs in any one of the display panel and the heat dissipation plate, only the abnormal configuration can be replaced, thereby reducing service costs.

Also, since the adhesive member is cut by the wire, separation can be achieved without damaging the display panel and the cover module.

Also, it is possible to separate the display panel and the heat dissipation plate while the gap between the display panel and the cover module is maintained sufficiently small.

Also, it is possible to prevent the occurrence of additional manufacturing costs by fixing the position of the wire using an opening, which is a conventional configuration.

Also, since the opening is located at the central portion of the cover body with respect to the left-and-right direction, it is possible to prevent the tension applied to the wire from being concentrated in either direction.

Also, since the burr of the heat dissipation plate faces the cover body, it is possible to prevent the wire from being cut by the burr.

Also, since the edge of the opening is formed to be round, it is possible to prevent the wire from being cut by the edge of the opening.

Also, it is possible to prevent the wire from being cut by the edge of the open portion by the guide jig in which the through hole having the round edge is formed.

Also, since at least one film is included in the adhesive member, the adhesive member attached to the display panel and the heat dissipation plate can be easily and clearly removed after separation is completed.

Also, the heat dissipation effect of dissipating heat from the display panel may be further increased by the film included in the adhesive member.

### DESCRIPTION OF DRAWINGS

FIG. 1 is a perspective view of a display device according to an embodiment of the present disclosure.

FIG. 2 is an exploded perspective view of a display module according to an embodiment of the present disclosure.

FIG. 3 is a rear perspective view of a display device according to an embodiment of the present disclosure.

FIG. 4 is an exploded perspective view of the display device illustrated in FIG. 3, in which a back cover and an electrical component are separated.

FIG. 5 is a rear view of a display panel according to an embodiment of the present disclosure.

FIG. 6 is a front view of a state in which a display panel is removed from a display module.

FIG. 7 is a view illustrating an example of an adhesive member that bonds a display panel to a heat dissipation plate.

FIG. 8 is a view a display device separation system according to an embodiment of the present disclosure.

FIG. 9 is a cross-sectional view of a display module illustrated in FIG. 8.

FIG. 10 is a view of a state in which the adhesive member illustrated in FIG. 7 is cut by a wire.

FIG. 11 is a view illustrating an example of a wire insertion mechanism.

FIG. 12 is a front view illustrating an example of a guide jig.

FIG. 13 is a cross-sectional view of a state in which the guide jig illustrated in FIG. 12 is installed in an opening.

FIG. 14 is a view illustrating another example of an adhesive member that bonds a display panel to a heat dissipation plate.

FIG. 15 is a view of a state in which the adhesive member illustrated in FIG. 14 is cut by a wire.

FIG. 16 is a view a display device separation system according to another embodiment of the present disclosure.

FIG. 17 is a view illustrating another example of an adhesive member of the present disclosure.

FIG. 18 is an exploded perspective view of a display module according to another embodiment of the present disclosure.

### MODE FOR DISCLOSURE

Hereinafter, specific embodiments of the present disclosure will be described in detail with reference to the accompanying drawings.

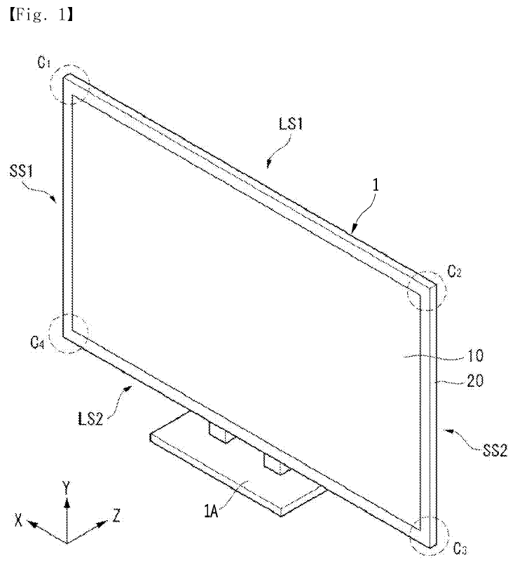

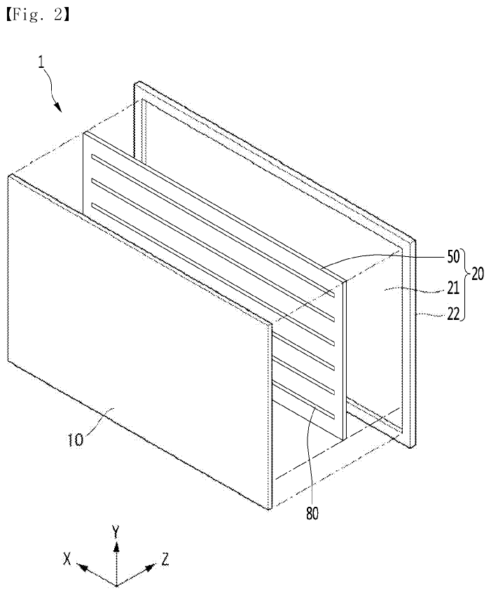

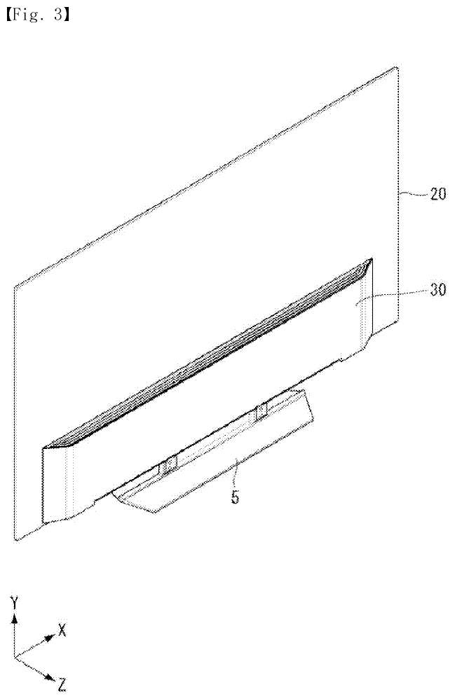

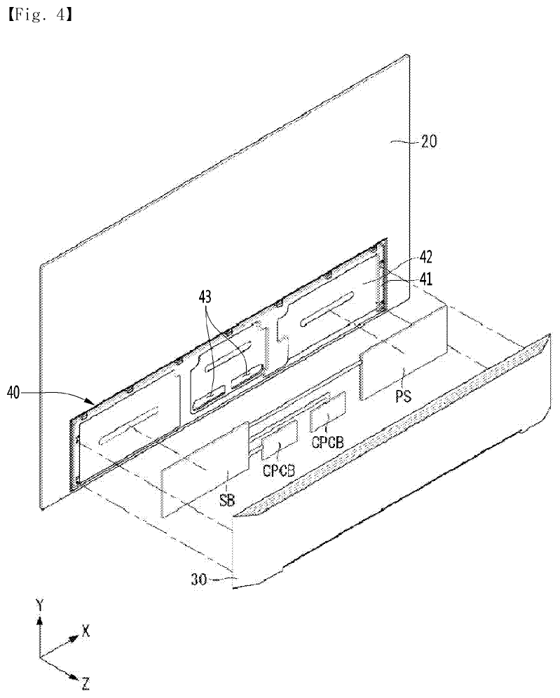

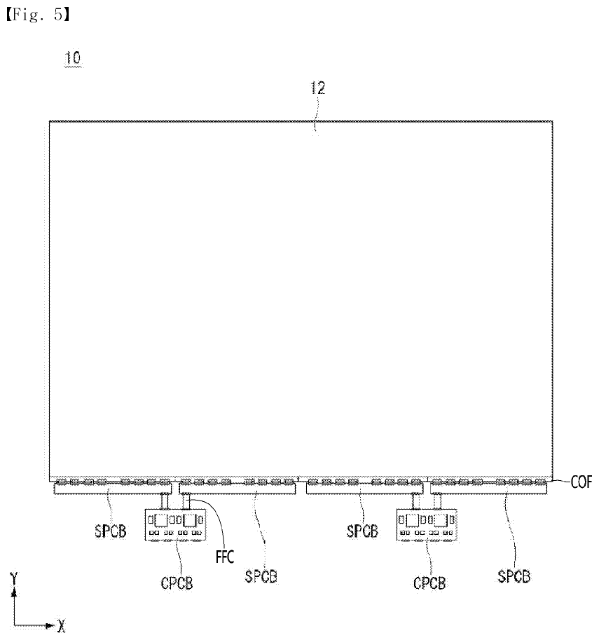

FIG. 1 is a perspective view of a display device according to an embodiment of the present disclosure, FIG. 2 is an exploded perspective view of a display module according to an embodiment of the present disclosure, FIG. 3 is a rear perspective view of a display device according to an embodiment of the present disclosure, FIG. 4 is an exploded perspective view of the display device illustrated in FIG. 3, in which a back cover and an electrical component are separated, and FIG. 5 is a rear view of a display panel according to an embodiment of the present disclosure.

A display device according to an embodiment of the present disclosure may include a display module 1, a stand 1A supporting the display module 1 from below, and a back cover 30 located at the rear of the display module 1.

The display module 1 may have an approximately rectangular plate shape. In more detail, the display module 1 may include a first long side LS1, a second long side LS2 facing the first long side LS1, a first short side SS1 adjacent to one end of the first long side LS1 and the second long side LS2, and a second short side SS2 facing the first short side SS1.

The first long side LS1, the second long side LS2, the first short side SS1, and the second short side SS2 may refer to the upper side, the lower side, the left side, and the right side of the display module 1, respectively.

The lengths of the first and second long sides LS1 and LS2 may be formed to be longer than the lengths of the first and second short sides SS1 and SS2, but the present disclosure is not limited thereto. The lengths of the first and second long sides LS1 and LS2 may be formed to be substantially identical to the lengths of the first and second short sides SS1 and SS2.

Also, a point at which the first long side LS1, the second long side LS2, the first short side SS1, and the second short side SS2 meet each other may be referred to as a corner. For example, a point at which the first long side LS1 and the first short side SS1 meet each other may be referred to as a first corner C1, a point at which the first long side LS1 and the second short side SS2 meet each other may be referred to as a second corner C2, a point at which the second short side SS2 and the second long side LS2 meet each other may be referred to as a third corner C3, and a point at which the second long side LS2 and the first short side SS1 meet each other may be referred to as a fourth corner C4.

The display module 1 may be supported by the stand 1A. The stand 1A may support the display module 1 at the bottom of the display module 1.

The display module 1 may include a display panel 10 that displays an image, and a cover module 20 that covers the display panel 10 from the rear.

The display panel 10 may be an OLED panel. The display panel 10 may display an image forward.

The cover module 20 may be configured as a rectangular frame. The cover module 20 may be made of a high-strength steel plate, for example, an electrogalvanized steel sheet (EGI), stainless steel (SUS), galvalume (SGLC), an aluminum plated steel sheet (ALCOSTA), a tin plated steel sheet (SPTE), and the like.

Also, the cover module 20 may be made of an advanced composite material (ACM) in which a carbon fiber, a silicon carbide fiber, an aramid fiber, a boron fiber, or the like is combined with a heat-resistant resin such as epoxy resin or polyimide.

When the cover module 20 is made of an ACM, a conductive tape may be attached to the inner surface of the cover module 20. The conductive tape may improve the coupling of the display panel 10 and reduce electromagnetic interference (EMI), thereby reducing noise mixed in an input image.

The cover module 20 may include a cover body 21 located at the rear of the display panel 10, and a cover circumference portion 22 protruding forward from the circumference of the cover body 21 and surrounding the outer circumference of the display panel 10. The cover module 20 may further include a heat dissipation plate 50 attached to the rear surface of the display panel 10 in the front-and-rear direction.

The cover body 21 may cover the rear surface of the display panel 10. The area of the cover body 21 may correspond to the area of the display panel 10.

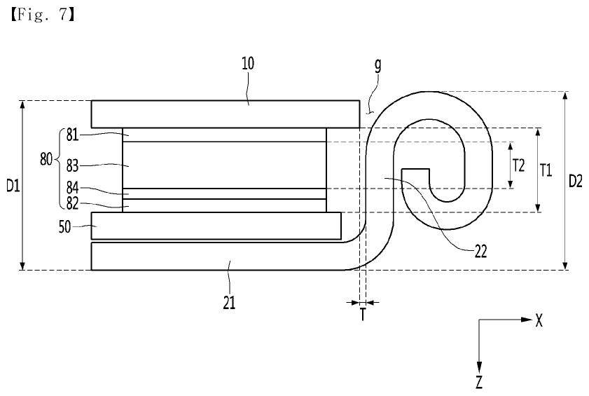

The cover circumference portion 22 may be provided along four sides of the display panel 10 to wrap around the outer circumferential edges of the display panel 10. The cover circumference portion 22 and the outer circumference of the display panel 10 may be spaced apart from each other to define a predetermined gap g (see FIG. 7). A distance T of the gap g may be approximately 0.5 mm, and the gap is very small so that foreign matters entering through the gap may be minimized.

The gap g may be formed along the circumferential direction of the display panel 10. In more detail, the gap g may include an upper gap, a lower gap, a left gap, and a right gap formed at the top, bottom, left, and right of the display panel 10.

An electrical component 40 may be provided on the rear surface of the cover module 20. In more detail, the electrical component 40 may be provided on the rear surface of the cover body 21. The electrical component 40 may be formed as a member separate from the cover module 20 and coupled to the cover module 20, or may be molded on the cover module 20 and formed integrally with the cover module 20.

The electrical component 40 may include a mounting portion 42 on which electrical components such as a system board SB and a power supply PS are mounted.

The system board SB may be referred to as a main board.

The system board SB may include a tuner that receives a broadcasting signal, an external device interface connected to an external device, a user interface device that receives a user input, and various sensors.

The power supply PS converts commercial AC power into driving power for the system board SB and a display panel driving circuit. The system board SB supplies DC input power from the power supply PS to the display panel driving circuit and transmits a video signal and a timing signal synchronized with the video signal to the display panel driving circuit.

The system board SB may be system boards for various display applications, such as a television system, a set-top box, a navigation system, a DVD player, a Blu-ray player, a personal computer (PC), a home theater system, a phone system, and a vehicle control system.

The heat dissipation plate 50 may be disposed between the cover body and the display panel 10. In more detail, the heat dissipation plate 50 may be disposed between the cover body 21 and a display 12 of the display panel 10, which will be described later.

The vertical length of the heat dissipation plate 50 may be shorter than the vertical length of the display panel 10. The heat dissipation plate 50 may dissipate heat generated from the display 12.

The heat dissipation plate 50 may be bonded to the rear surface of the display panel 10 by the adhesive member 80.

Meanwhile, the back cover 30 may cover the electrical component 40 from the rear. The back cover 30 may be coupled to the rear surface of the cover body 21 or the electrical component 40. The method of coupling the back cover 30 and the electrical component 40 or the back cover 30 and the cover body 210 may be changed as necessary. For example, a latch accommodating portion (not illustrated) may be formed at the edge of the electrical component 40, and a plurality of latches (not illustrated) protruding toward the electrical component 40 and fixed to the latch accommodating portion may be provided on the inner wall of the back cover 30.

Meanwhile, the display panel 10 may include a display 12, and a driving circuit for writing data of an input image to the display 12. The driving circuit may include a data driving circuit that supplies a data voltage of an input image to data lines of the display 12, a scan driving circuit (or gate driving circuit) that sequentially supplies, to scan lines of the display 12, a scan signal (or gate pulse) synchronized with the data voltage, and a timing controller (T-con) that controls the operation timing of the data driving circuit and the scan driving circuit.

A screen of the display 12 includes a pixel array on which an input image is displayed. In the pixel array, pixels are arranged in a matrix form by an intersection structure of the data lines and the scan lines. The pixels may include red (R), green (G), and blue (B) sub-pixels for color implementation. Each of the pixels may further include a white (W) sub-pixel. Each of the sub-pixels may include a thin film transistor (TFT) that supplies a data voltage from a data line to a pixel electrode in response to a scan pulse. In the case of an OLED display device, each of sub-pixels may include a switch TFT, a driving TFT, an OLED, or the like. The driving TFT is a driving element that adjusts a current flowing through the OLED according to data of an input image.

The data driving circuit may be integrated in a source drive integrated circuit (IC). The source drive IC may be mounted on a chip on film (COF). The COF may be bonded to data pads of the display 12 with an anisotropic conductive film (ACF), and the data pads may be connected to data lines. The data driving circuit may sample digital data of an input image received from the timing controller (T-con). The data driving circuit may generate a data voltage by converting the sampled digital data into a gamma compensation voltage using a digital-to-analog converter. Also, the data driving circuit may output the data voltage to the data lines.

The COF may be configured to connect the display 12 and the source board SPCB.

The scan driving circuit may be directly formed on a substrate of the display 12 through a gate in panel (GIP) process and connected to the scan lines. The IC in which the scan driving circuit is integrated may be bonded to the gate pads of the display with ACF in a tape automated bonding (TAB) process. The scan pads are connected to the scan lines. The scan driving circuit may sequentially supplying scan pulses synchronized with the data voltage to the scan lines using a shift register that receives a start pulse and a shift clock and sequentially outputs the start pulse and the shift clock in synchronization with a clock timing.

The timing controller (T-con) receives digital data of an input image from the system board SB and transmits the digital data to the source drive IC (SIC). The timing controller (T-con) may receive timing signals such as vertical/horizontal synchronization signals, data enable, and main clock signals and generate timing control signals for controlling the operation timing of the source drive IC (SIC) and the scan driving circuit.

The timing controller (T-Con) may multiply a frame frequency by N times (N is a positive integer greater than or equal to 2) the input frame frequency and control the display panel driving circuit based on the multiplied frame frequency. The input frame frequency may be 50 Hz in a Phase Alternate Line (PAL) scheme and 60 Hz in a National Television Standards Committee (NTSC) scheme.

The timing controller (T-Con), a level shifter, a power management integrated circuit (PMIC), and the like may be mounted on a control board CPCB. The PMIC may generate a voltage required for driving the display 12 from a DC voltage supplied from the system board SB using a DC-DC converter.

The control board CPCB may be connected to the source board SPCB through a flexible flat cable FFC. The control board CPCB may be mounted on the mounting portion 42 of the electrical component 40, and the source board SPCB may be included in the display panel 10 and located in front of the electrical component 40. Therefore, the flexible flat cable FFC may connect the control board CPCB and the source board SPCB by passing through the opening 43 defined in the electrical component 40.

The level shifter may shift the voltage level of the gate timing control signal, converts the gate timing control signal into a signal swinging between a gate high voltage (VGH) and a gate low voltage (VGL), and converts the signal to the shift register. The gate high voltage VGH may be set to a voltage higher than a threshold voltage of the TFT disposed in each of the sub-pixels. The gate low voltage VGL may be set to a voltage lower than the threshold voltage of the TFT. The TFT may be turned on in response to the VGH voltage of the scan pulse, and may be turned off in response to the VGL voltage.

In the case of a large-screen display device, a plurality of display panel driving circuits may be connected to the display 12 and may divide and drive the screen of the display 12.

Such a driving circuit may be implemented through a driving circuit mounting process. In the driving circuit mounting process, the IC of the data driving circuit may be mounted on the substrate of the display 12 using a chip on glass (COG) process or a tape automated bonding (TAB) process. The scan driving circuit may be directly formed on the substrate of the display unit by the Gate in Panel (GIP) process, or may be attached to the substrate by the TAB process in the driving circuit mounting process. Subsequently, in the driving circuit mounting process, the IC and the source board SPCB may be connected with a flexible cable such as a flexible printed circuit board (FPC) or a flexible flat cable (FFC).

Meanwhile, a pair of openings 43 may be defined in the electrical component 40. A cable (e.g., FFC) connecting the system board SB mounted on the mounting portion 41 of the electrical component 40 and the control board CPCB of the display panel 10 may pass through the opening defined in the electrical component 40. Also, when the display device is separated, a wire 90 (see FIG. 9) to be described later may pass through the opening 43, and the opening 43 may function as a wire passage hole.

The pair of openings 43 may be located in the central portion of the cover body 21 with respect to the left-and-right direction. The central portion does not mean only the exact middle line of the cover body 21, but may mean a position closer to the middle line than the left and right edges of the cover body 21.

Also, the opening 43 may communicate with the space below the heat dissipation plate 50. That is, the opening 43 may non-overlap the heat dissipation plate 50 in the front-and-rear direction.

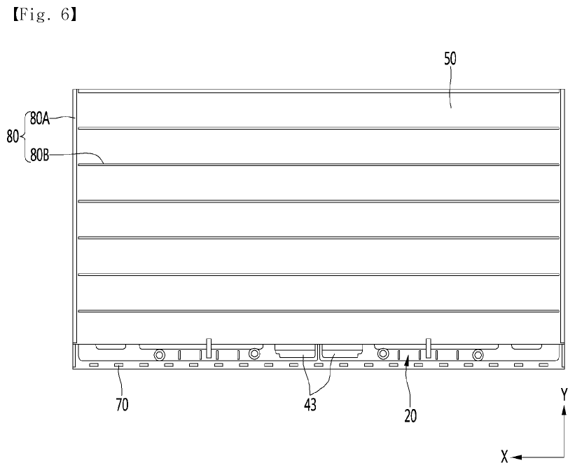

FIG. 6 is a front view of a state in which the display panel is removed from the display module, and FIG. 7 is a view illustrating an example of the adhesive member that bonds the display panel to the heat dissipation plate.

The display module 1 according to the present embodiment may include a plurality of adhesive members 80 for bonding the heat dissipation plate 50 to the display panel 10. The rear surface of the display panel 10 may be bonded to the front surface of the heat dissipation plate 50 by the adhesive member 80.

During the process of assembling the display module 1, the adhesive member 80 may be bonded to the front surface of the heat dissipation plate 50. Thereafter, the rear surface of the display panel 10 may be brought close to the adhesive member 80 to bond the display panel 10 to the heat dissipation plate 50.

Each adhesive member 80 may be configured as a double-sided adhesive tape.

The plurality of adhesive members 80 may include an outer adhesive member 80A attached to the front edge of the heat dissipation plate 50, and an inner adhesive 80B attached to the inner side of the outer adhesive member 80A among the front surfaces of the heat dissipation plate 50. Each of the outer adhesive member 80A and the inner adhesive member 80B may be plural.

For example, the outer adhesive member 80A may be attached to the upper edge, the left edge, and the right edge of the front surface of the heat dissipation plate 50.

Also, the plurality of inner adhesive members 80B may be attached to be spaced apart from each other at predetermined intervals in the vertical direction. Each of the inner adhesive members 80B may be formed to be elongated in the left-and-right direction and may be attached side by side.

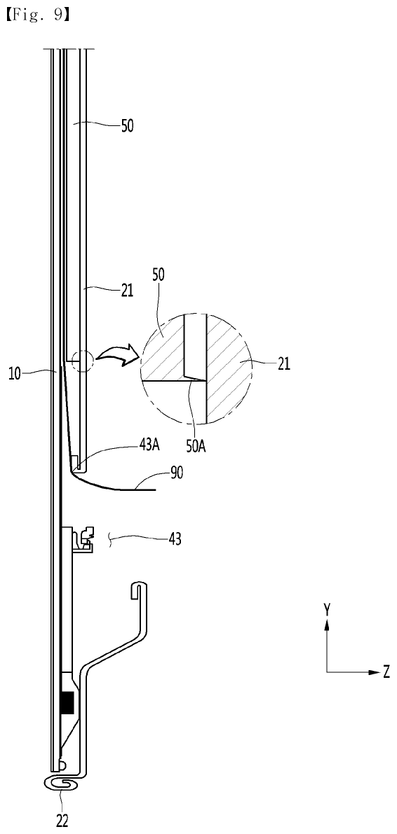

When the display module 1 is separated, the wire 90 (see FIG. 10) may penetrate from the outside to the inside of the outer adhesive member 80A and cuts the outer adhesive member 80A and the inner adhesive member 80B. This will be described in detail below.

The adhesive member 80 may have a thickness that is much thinner than that of each of the display panel 10 and the heat dissipation plate 50, and thus the display module 1 may be manufactured to be thinner. For example, a thickness T1 of the adhesive member 80 may be approximately 0.5 mm.

Also, a length corresponding to the thickness T1 of the adhesive member 80 may be shorter than a length corresponding to the minimum distance between one adhesive member 80 and the other adhesive member 80 adjacent to the one adhesive member 80.

The adhesive member 80 may include a first adhesive layer 81 attached to the rear surface of the display panel 10, a second adhesive layer 82 attached to the front surface of the heat dissipation plate 50, and a base layer 83 located between the first adhesive layer 81 and the second adhesive layer 82. The adhesive member 80 may further include a film 84 located between the second adhesive layer 82 and the base layer 83.

The first adhesive layer 81 and the second adhesive layer 82 may be formed by being applied to both surfaces of the adhesive member 80. The first adhesive layer 81 and the second adhesive layer 82 may include an acrylic adhesive.

The base layer 83 may have a polyurethane (PU) foam material. That is, since the base layer 83 is made of a foam material having relatively weak rigidity, the base layer 83 may be easily cut by the wire 90 to be described later.

Also, the film 84 may be made of polyethylene terephthalate (PET). The second adhesive layer 82 may be easily removed from the heat dissipation plate 50 by the film 84.

A thickness T2 of the base layer 83 may be formed to be greater than that of each of the first adhesive layer 81, the second adhesive layer 82, and the film 84. Also, the thickness T2 of the base layer 83 may be 70% or more of the thickness T1 of the adhesive member 80. For example, the thickness T2 of the base layer 83 may be approximately 0.36 mm, and the thickness of the first adhesive layer 81, the second adhesive layer 82, and the film 84 may be 0.05 mm or less.

In addition, since the thickness of the base layer 83 is relatively thick, the first adhesive layer 81, the second adhesive layer 82, and the film 84 are not cut by the wire 90, and the base layer 83 may be cut.

Meanwhile, the display module 1 according to the present embodiment may include a plurality of auxiliary adhesive members 70 for bonding the cover body 21 of the cover module 20 to the display panel 10.

The auxiliary adhesive member 70 may be configured as a double-sided adhesive tape.

The auxiliary adhesive member 70 may be provided below the heat dissipation plate 50. The lower rear surface of the display panel 10 may be bonded to the lower front surface of the cover body 21 by the auxiliary adhesive member 70.

A plurality of auxiliary adhesive members 70 may be provided on the lower edge of the front surface of the cover body 21. The plurality of auxiliary adhesive members 70 may be attached to be spaced apart from each other by a predetermined interval.

When the display module 1 is separated, the auxiliary adhesive member 70 may be preferentially removed before the wire 90 (see FIG. 10) is inserted into the gap g between the display panel 10 and the cover circumference 22. This will be described in detail below.

Meanwhile, the cover circumference portion 22 may protrude forward from the display panel 10. That is, the front-and-rear distance D1 from the rear surface of the cover body 21 to the front surface of the display panel 10 may be shorter than the front-and-rear distance D2 from the rear surface of the cover body 21 to the front end of the cover circumferential portion 10.

Thus, the display panel 10 may be safely protected by the cover circumference portion 22.

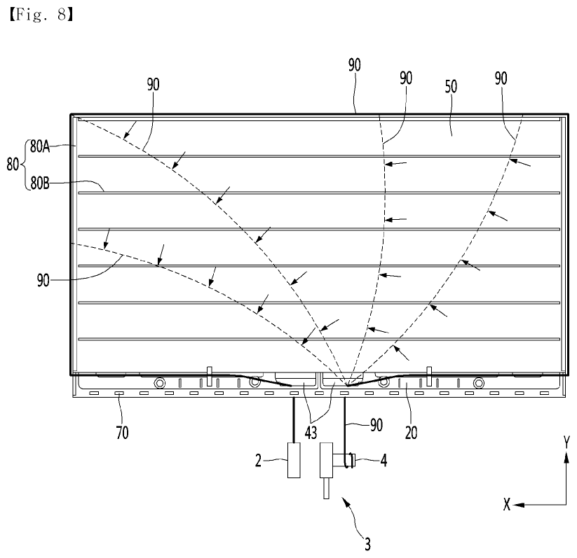

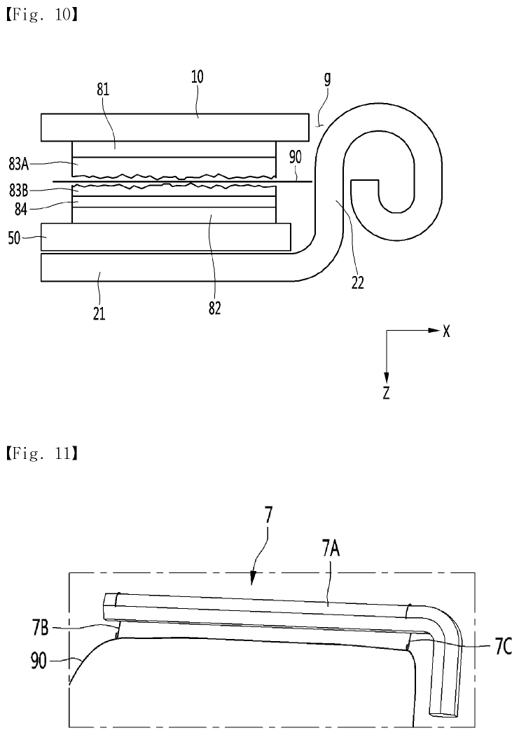

FIG. 8 is a view a display device separation system according to an embodiment of the present disclosure, FIG. 9 is a cross-sectional view of the display module illustrated in FIG. 8, FIG. 10 is a view of a state in which the adhesive member illustrated in FIG. 7 is cut by the wire, and FIG. 11 is a view illustrating an example of a wire insertion mechanism.

The display device may be separated when repair or maintenance is required.

An operator may remove the back cover 30 (see FIG. 4) from the cover module 20 and may separate the system board SB, the power supply PS, and the control board CPCB from the electrical component 40.

Also, the auxiliary adhesive member 70 may be separated in the process of pulling the FFC (see FIG. 5) connected to the control board CPCB between the lower portion of the cover module 20 and the lower portion of the display panel 10.

In more detail, in order to facilitate the separation of the auxiliary adhesive member 70, the operator may open the gap between the lower end of the display panel 10 and the lower end of the cover module 20 by pulling the display panel 10 forward using an adsorption mechanism or the like, and may pull the FFC through the gap. In the process of pulling the FFC, the operator may separate the auxiliary adhesive member 70 while moving the FFC to the left or right.

Thereafter, the operation of separating the display module 1 may be performed.

The display device separation system according to the embodiment of the present disclosure may include a display module 1, a wire 90 for cutting the adhesive member 80, and an electromotive jig 3 for winding the wire 90. The display device separation system may further include a fixing portion 2 for fixing the wire 90.

The display panel 10 of the display module 1 may be separated from the cover module 20 by the wire 90. In more detail, the adhesive member 80 bonding the display panel 10 to the heat dissipation plate 50 may be cut in the thickness direction by the wire 90, and thus the display panel 10 and the heat dissipation plate 50 may be separated.

The wire 90 may be located between the display panel 10 and the cover module 20 along the circumference of the display panel 10. In more detail, the wire 90 is inserted into the gap g between the outer circumference of the display panel 10 and the cover circumference portion 22 and enters between the display panel 10 and the heat dissipation cover 50. Thereafter, the wire 90 moves to cut the adhesive member 80 in the thickness direction.

The wire 90 may be made of a material having a strong tension and a thin thickness, such as a fishing line or a piano line. Also, the wire 90 may have a non-metallic material. When the wire 90 is made of a metal material, there is a concern that the wire 90 may damage the display panel 10 in the process of cutting the adhesive member 80. On the other hand, the wire 90 made of a non-metallic material may withstand sufficient tension, but is broken when a certain impact or more is applied to the display panel 10. Thus, the possibility of damaging the display panel 10 may be reduced. For example, the wire 90 may include at least one of plastic, Kevlar fiber, carbon fiber, and polyethylene fiber.

The wire 90 may have a thickness enough to pass through the gap g between the outer circumference of the display panel 10 and the cover circumference portion 22.

Also, the thickness of the wire 90 may be thinner than the thickness of the adhesive member 80, and preferably may be thinner than the thickness of the base layer 83. Therefore, damage to the display panel 10 may be minimized while the wire 90 cuts the adhesive member 80.

Also, the thickness of the wire 90 may be at least half of the thickness of the base layer 83. Therefore, in the process of cutting the adhesive member 80, the wire 90 is not broken and withstands sufficient tension.

The wire 90 may be inserted into the gap g by the insertion mechanism 7. The insertion mechanism 7 may include a main body 7A and a locking portion 7B connected to the main body 7A and configured to catch the wire 90. The insertion mechanism 7 may further include a guide portion 7C spaced apart from the locking portion 7B and configured to catch the wire 90.

The main body 7A may have a bar shape. The main body 7A may serve as a gripping portion.

At least a part of the locking portion 7B may be formed in a loop or ring shape. The locking portion 7B may be provided at a position adjacent to one end of the main body 7A.

The locking portion 7B may have a thickness that can be inserted into the gap g. When the wire 90 is caught in the locking portion 7B, the locking portion 7B may be inserted into the gap g, so that the wire 90 may be inserted into the cover module 20.

At least a part of the guide portion 7C may be formed in a loop or ring shape. The locking portion 7B may be provided at a position relatively far from the one end of the main body 7A. The guide portion 7C may prevent the wire 90 from being twisted or entangled in the process of inserting the wire 90 into the inside of the cover module 20 and may improve user convenience.

Meanwhile, the electromotive jig 3 may include a motor (not illustrated) and a rotating portion 4 rotated by the motor. The rotating portion 4 may be formed in an approximately cylindrical shape, and the wire 90 may be wound around the rotating portion 4 as the rotating portion 4 rotates.

The fixing portion 2 may be an element separate from the display module 1, but the present disclosure is not limited thereto.

One end of the wire 90 may be fixed to the fixing portion 2, and the other end of the wire 90 may be connected to the electromotive jig 3, and more specifically, the rotating portion 4.

While the wire 90 passes through the opening 43 and is connected to the electromotive jig 3, the wire 90 may be wound around the rotating portion 4 of the electromotive jig by the operation of the electromotive jig 3 and the adhesive member 80 may be cut.

Hereinafter, a method of separating the display device, and more particularly, the display module 1 will be described in more detail.

The display device separation method according to an embodiment of the present disclosure may include a fixing operation of fixing a point of the wire 90, an inserting operation of inserting the wire 90 into the gap g between the display panel 10 and the cover circumference portion 22 along the circumferential direction of the display panel 10, a connecting operation of connecting the other point of the wire 90 to the electromotive jig 3, a cutting operation of cutting the adhesive member 80 between the display panel 10 and the heat dissipation plate 50 while winding the wire 90 by the operation of the electromotive jig 3, and a separating operation of separating the display panel 10 and the heat dissipation plate 50.

During the fixing operation, one point of the wire 90 may be fixed to the fixing portion 2. For example, one end of the wire 90 may be fixed to the fixing portion 2.

The inserting operation may include an operation of passing the wire 90 through the one opening 43 defined in the electrical component 40, an operation of inserting the wire 90 into the gap g using the insertion mechanism 7 through which the wire 90 is caught, an operation of moving the insertion mechanism 7 along the circumferential direction of the display panel 10 while the wire 90 is caught, and an operation of passing the end of the wire 90 inserted into the gap g through the other opening 43 defined in the electrical component 40.

In more detail, the wire 90 may pass from the rear of the one opening 43 forward to the front, and then come out through the gap between the lower end of the display panel 10 and the lower end of the cover module 20.

Hereinafter, for convenience of description, a case in which the one opening 43 is the left opening among a pair of openings will be described as an example.

The wire 90 coming out through the gap between the lower end of the display panel 10 and the lower end of the cover module 20 may be inserted into the gap g between the outer circumference of the display panel 10 and the cover circumference portion 22 by the insertion mechanism 7. That is, the operator may hook the wire 90 to the locking portion 7B and the guide portion 7C of the insertion mechanism 7 and insert the locking portion 7B into the gap g.

A position at which the locking portion 7B is inserted into the gap g may be a position adjacent to the one opening 43. The locking portion 7B may be inserted into the gap g defined under the display panel 10, that is, the lower gap.

When the locking portion 7B in which the wire is caught is inserted into the gap g, the insertion mechanism 7 moves along the circumferential direction of the display panel 10 and the wire 90 may be inserted long.

For example, the insertion mechanism 7 may maintain the state in which the locking portion 7B is inserted into the gap g, and may move along the lower gap, the left gap, the upper gap, the right gap, and the lower gap.

In the above process, the wire 90 may be caught by the adhesive member 80, and more specifically, the outer adhesive member 80A, and may not penetrate between the display panel 10 and the heat dissipation plate 50. That is, the wire 90 may be located outside the outer adhesive member 80A within the cover module 20.

However, since the auxiliary adhesive member 70 is already separated, the wire 90 may not be caught by the auxiliary adhesive member 70. That is, the portion of the wire inserted into the lower gap g may be moved upward without being caught by the auxiliary adhesive member 70 due to the tension of the wire 90.

Thereafter, the wire 90 may pass through the other opening 43. As an example, the other opening 43 may be the right opening among the pair of openings. The wire 90 may pass from the front to the rear of the other opening 43.

Therefore, the wire 90 may form a rectangular ring shape that is disposed to surround the circumference of the heat dissipation plate 50. Also, since the wire 90 has passed through the pair of openings 43, the position of the wire 90 may be fixed by the opening 43.

In the connecting operation, the wire 90 passing through the other opening 43 may be connected to the electromotive jig 3.

During the cutting operation, when the electromotive jig 3 is operated, the rotating portion 4 connected to the motor may be rotated and the wire 90 may be wound.

As the wire 90 is wound, the tension applied to the wire 90 may increase, and the wire 90 may be cut by digging the adhesive member 80 from the outside to the inside.

The wire 90 may cut the adhesive member 80 with respect to the thickness direction of the adhesive member 80. In more detail, the base layer 83 of the adhesive member 80 may be cut by the wire 90. The base layer 83 cut by the wire 90 may be divided into a panel-side base layer 83A and a plate-side base layer 83B.

Since the pair of openings 43 are located at the central portion of the cover body 21 with respect to the left-and-right direction, tension applied to the wire 90 may be prevented from being concentrated in either direction.

The wire 90 may penetrate from the outside of the outer adhesive member 80A and cut the outer adhesive member 80A and the inner adhesive member 80B.

In this process, the ring shape formed by the wire 90 may become smaller. After all the adhesive members are cut, the wire 90 may come out from the display module 1 through the opening 43.

Therefore, the plurality of adhesive members 80 can be cut simultaneously by the wire 90, thereby reducing the required time. Also, damage or deformation of the display panel 10 and the heat dissipation plate 50 may be minimized, and the adhesive member 80 may be cut.

The separating operation may be performed after the cutting operation.

In the separating operation, the display panel may be separated from the cover module. Since the adhesive member 80 bonding the display panel 10 to the heat dissipation plate 50 is in a cut state, the operator may separate the display panel 10 from the cover module 20 using an adsorption mechanism or the like.

Thus, even when a problem occurs in any one of the display panel 10 and the cover module 20, only the corresponding part may be replaced without replacing the entire display module 1, thereby reducing service costs.

Meanwhile, a burr 50A formed around the heat dissipation plate 50 may face the cover body. The burr 50A may refer to a sharp portion generated at an edge portion during a process of cutting a material during the manufacturing and processing of the heat dissipation plate.

The heat dissipation plate 50 may be disposed so that the burr 50A faces the opposite side of the display panel 10, that is, the cover body 21. Therefore, it is possible to prevent the wire 90 from being disconnected by the burr 50A while the wire 90 penetrates into the heat dissipation plate 50 and the display panel 10.

Also, an edge 43A of the opening 43 defined in the electrical component 40 may be formed to be round. Since the cutting operation is performed in a state in which the wire 90 passes through each of the pair of openings 43, it is possible to prevent a phenomenon in which the wire 90 is disconnected by the edge 43A of the opening 43 in a state in which the wire 90 is tightened by tension.

On the other hand, after the separating operation described above, the display device separation method may further include a removing operation of removing the adhesive member 80 bonded to the display panel 10 and the heat dissipation plate 50.

When the display panel 10 and the cover module 20 are separated, the adhesive member attached to the rear surface of the display panel 10 may include a first adhesive layer 81 and a panel-side base layer 83A, and the adhesive member attached to the front surface of the heat dissipation plate 50 may include a second adhesive layer 82, a film 84, and a plate-side base layer 83B.

In order to reuse the display panel 10 or the heat dissipation plate 50, the adhesive member 80 attached to each element may be removed.

In particular, the adhesive member attached to the front surface of the heat dissipation plate 50 may be easily removed from the heat dissipation plate 50 by the film 84. Since such an action of the film 84 is a known technique, a detailed description thereof is omitted.

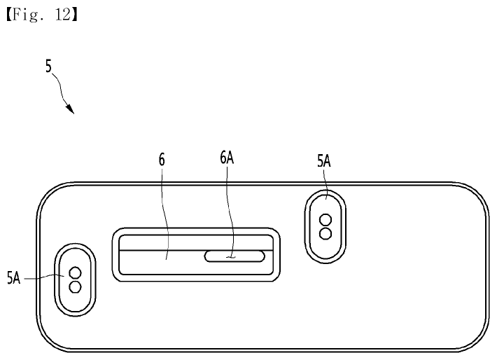

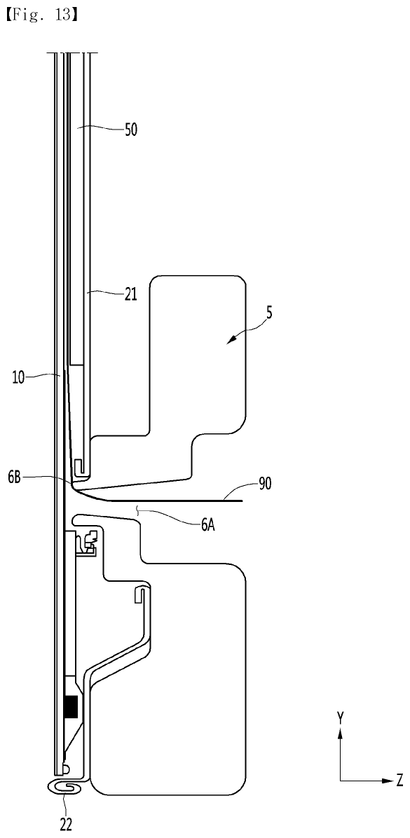

FIG. 12 is a front view illustrating an example of a guide jig, and FIG. 13 is a cross-sectional view of a state in which the guide jig illustrated in FIG. 12 is installed in the opening.

The display device separation system may further include a guide jig 5.

Instead of forming the edge 43A of the opening 43 to be round, it is possible to prevent the wire 90 from being cut by using the guide jig 5. Hereinafter, the guide jig 5 will be described.

The display device separation method may further include a jig installing operation of installing, in the electrical component 40, the guide jig 5 corresponding to the opening 43, having an edge 6B round, and having at least one through hole 6A through which the wire 90 passes.

At least one coupling portion 5A and at least one through hole 6A may be defined in the guide jig 5.

The guide jig 5 may be mounted on the rear surface of the cover module 20. In more detail, the guide jig 5 may be seated and coupled to the rear surface of the electrical component 40. The coupling of the guide jig 5 may be performed prior to the operation of inserting the wire 90 described above.

In more detail, a coupling hole (not illustrated) for coupling the guide jig 5 may be formed in the electrical component 40 formed in the cover body 21. The coupling hole may also serve to couple the electrical part (for example, the system board) connected to the electrical component 40.

A coupling member such as a screw may pass through the coupling portion 5A of the guide jig 5 and the coupling hole defined in the electrical component 40 and may couple the guide jig 5 to the electrical component 40.

When the guide jig 5 is coupled to the electrical component 40, the opening 43 may correspond to the through hole 6A defined in the guide jig 5. In more detail, the guide jig 5 may have a protrusion that is inserted and seated into the opening 43, and the through hole 6A may be defined through the protrusion. Therefore, during the inserting operation, the wire 90 may pass through the through hole 6A of the guide jig 5 and enter the inside of the display module 1.

In this case, the edge 6B of the through hole 6A of the guide jig 5 may be formed to be round. Since the cutting operation is performed in a state in which the wire 90 passes through the through hole 6A of the guide jig 5, it is possible to prevent a phenomenon in which the wire 90 is disconnected by the edge 6B of the through hole 6A in a state in which the wire 90 is tightened by tension.

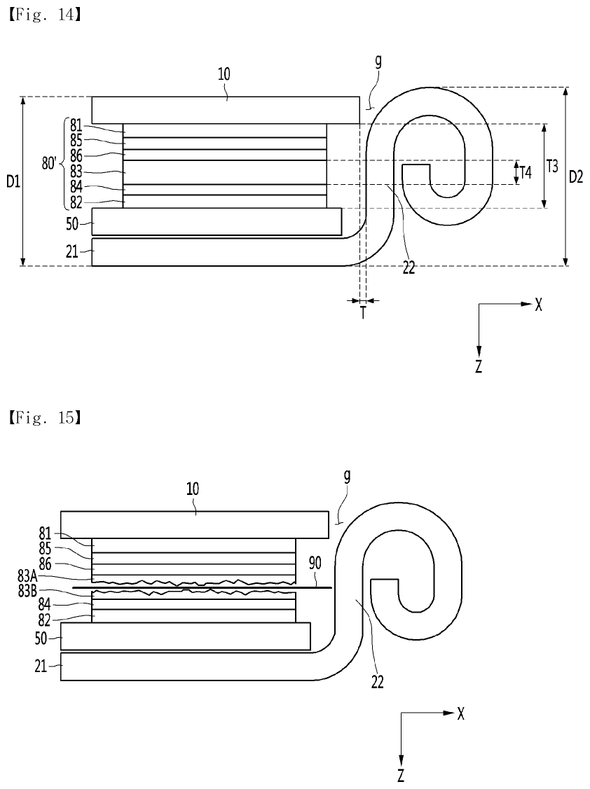

FIG. 14 is a view illustrating another example of an adhesive member that bonds a display panel to a heat dissipation plate, and FIG. 15 is a view of a state in which the adhesive member illustrated in FIG. 14 is cut by a wire.

An adhesive member 80′ according to the present example may include a first adhesive layer 81, a second adhesive layer 82, a base layer 83, a first film 85, and a second film 84. The adhesive member 80′ may further include an auxiliary adhesive layer 86.

The first adhesive layer 81, the second adhesive layer 82, and the base layer 83 may correspond to the first adhesive layer, the second adhesive layer, and the base layer of the adhesive member 80 described above, respectively. Also, the second film 84 may have a configuration corresponding to the film of the adhesive member 80 according to the example described above. Therefore, redundant descriptions thereof will be omitted.

The first film 85 may be located between the first adhesive layer 81 and the base layer 83.

The material of the first film 85 may be different from that of the second film 84. For example, the first film 85 may be a PU film, and the material of the second film 84 may be polyethylene terephthalate (PET).

The first film 85 may increase a heat dissipation effect for dissipating heat generated from the display panel.

In addition, the first adhesive layer 81 may be easily and clearly removed from the display panel 10 by the first film 85.

The auxiliary adhesive layer 86 may be located between the first film 85 and the base layer 83. The auxiliary adhesive layer 86 may include an acrylic adhesive.

A thickness T4 of the base layer 83 may be greater than that of each of the first adhesive layer 81, the second adhesive layer 82, the first film 85, and the second film 84. Also, the thickness T4 of the base layer 83 may be 70% or more of the thickness T3 of the adhesive member 80′. For example, the thickness T4 of the base layer 83 may be approximately 0.36 mm, and thickness of the first adhesive layer 81, the second adhesive layer 82, and the and second film 85 and 84 may be 0.05 mm or less.

Since the thickness of the base layer 83 is relatively thick, the first adhesive layer 81, the second adhesive layer 82, and the first and second film 85 and 84 are not cut by the wire 90, and the base layer 83 may be cut.

The first and second films 85 and 84 may facilitate the removal of the adhesive member 80′ attached to the display panel 10 during the removing operation.

In more detail, when the display panel 10 and the cover module 20 are separated, the adhesive member attached to the rear surface of the display panel 10 may include a first adhesive layer 81, a first film, an auxiliary adhesive layer 86, and a panel-side base layer 83A. The adhesive member attached to the front surface of the heat dissipation plate 50 may include a second adhesive layer 82, a second film 84, and a plate-side base layer 83B.

In order to reuse the display panel 10 or the heat dissipation plate 50, the adhesive member 80 attached to each element may be removed.

In particular, the adhesive member attached to the rear surface of the display panel 10 may be easily removed from the display panel 10 by the first film 85. Also, the adhesive member attached to the front surface of the heat dissipation plate 50 may be easily and clearly removed from the heat dissipation plate 50 by the second film 84. Since such an action of the first and second films 85 and 84 is a known technique, a detailed description thereof is omitted.

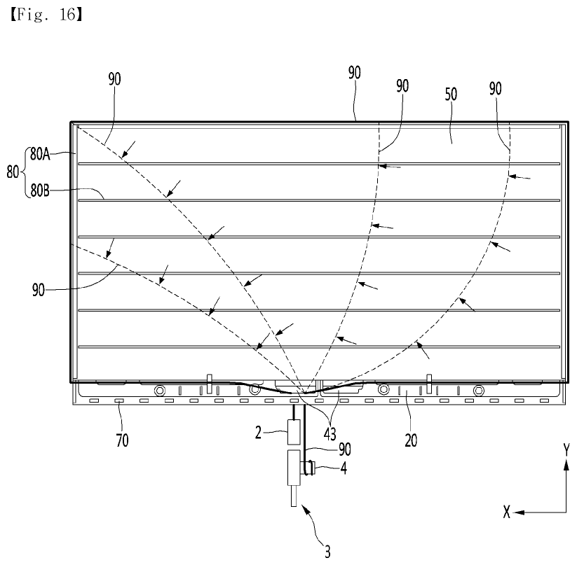

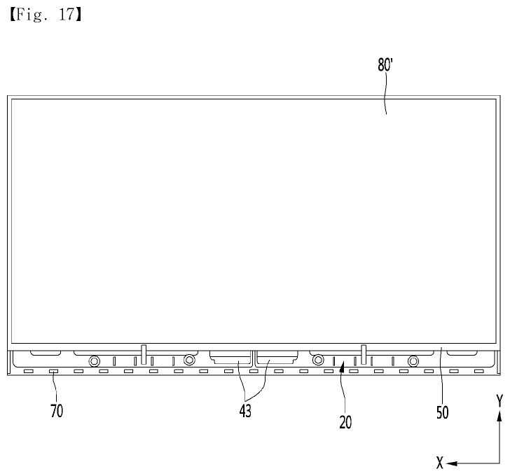

FIG. 16 is a view a display device separation method according to another embodiment of the present disclosure.

Hereinafter, contents overlapping with the above-described contents will be omitted, and the differences will be mainly described.

In the case of the display device separation system according to the embodiment described above, the wire 90 may be wound around the electromotive jig 3 while passing through one opening and the other opening. On the other hand, in the case of the display device separation system according to the present embodiment, the wire 90 may be wound around the electromotive jig 3 while passing through one opening twice.

In more detail, the inserting operation of inserting the wire 90 into the gap g between the display panel 10 and the cover circumference portion 22 may include an operation of passing the wire 90 through one opening 43 defined in the electrical component 40, an operation of inserting the wire 90 into the gap g using the insertion mechanism 7 through which the wire 90 is caught, an operation of moving the insertion mechanism 7 along the circumferential direction of the display panel 10 while the wire 90 is caught, and an operation of passing the end of the wire 90 inserted into the gap g through the one opening 43.

Since the wire 90 has passed through the one opening 43, the position of the wire 90 may be fixed by the one opening 43.

Also, when the display device separation system includes the guide jig 5, the through hole 6A of the guide jig 5 may correspond to the one opening 43.

FIG. 17 is a view illustrating another example of an adhesive member of the present disclosure.

Hereinafter, except for the configuration of the adhesive member 80′, the following description is the same as that described above, and thus, overlapping content will be omitted and the differences will be mainly described.

The adhesive member 80′ may bond the rear surface of the display panel 10 to the front surface of the heat dissipation plate 50, and one adhesive member 80′ may be provided. For example, the adhesive member 80′ may be a single member covering most of the front surface of the heat dissipation plate 50.

The configuration of the adhesive member 80′ may further strengthen the adhesive force between the rear surface of the display panel 10 and the heat dissipation plate 50.

Also, according to the display device separation method described above, the adhesive member 80′ may be cut and separated by the wire 90 inserted between the display panel 10 and the cover module 20. The wire 90 may cut the adhesive member 80′ by digging from the outside to the inside of the adhesive member 80′. Thus, even when the size of the adhesive member 80′ is large, the adhesive member 80′ can be easily cut by the wire 90′.

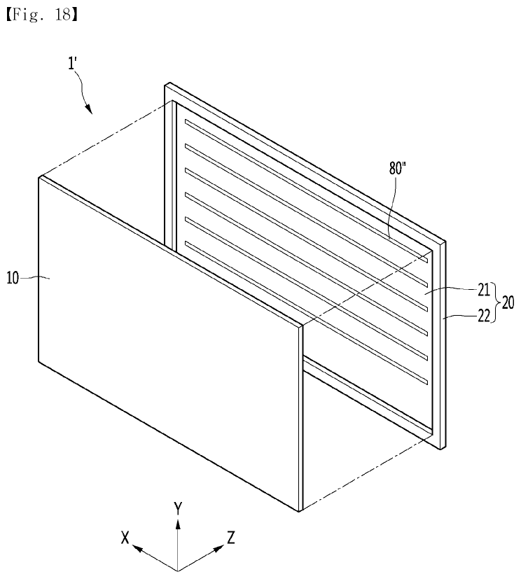

FIG. 18 is an exploded perspective view of a display module according to another embodiment of the present disclosure.

Hereinafter, contents overlapping with the above-described contents will be omitted, and the differences will be mainly described.

The display module 1′ according to the present embodiment may include a display panel 10 and a cover module 20. In this case, the cover module 20 includes a cover body 21 and a cover circumference portion 22, and may not include a heat dissipation cover.

An adhesive member 80″ is located between the display panel 10 and the cover body 21 and may bond the display panel 10 to the cover body 21. It is preferable that a plurality of adhesive members 80″ are provided, but only one adhesive member 80″ may be provided.

The adhesive member 80″ may be attached to and provided on the front surface of the cover body 21, and the display panel 10 may be attached to the adhesive member 80″. Therefore, the rear surface of the display panel 10 and the front surface of the cover body 21 may be attached to each other.

The wire 90 entered through the gap between the cover circumference portion 22 and the display panel 10 may penetrate between the display panel 10 and the cover body 21 to cut the adhesive member 80″. Therefore, the display panel 10 and the cover module 20 may be easily separated.

When the display device separation method according to the present embodiment further includes a jig installing operation, one through hole 6A (see FIG. 12) may be defined in the guide jig 5. That is, there is an advantage that the configuration required for the guide jig 5 becomes simple.

The above description is merely illustrative of the technical idea of the present disclosure, and various modifications and changes may be made thereto by those skilled in the art without departing from the essential characteristics of the present disclosure.

Therefore, the embodiments of the present disclosure are not intended to limit the technical spirit of the present disclosure but to describe the technical idea of the present disclosure, and the technical spirit of the present disclosure is not limited by these embodiments.

The scope of protection of the present disclosure should be interpreted by the appending claims, and all technical ideas within the scope of equivalents should be construed as falling within the scope of the present disclosure.

1. A display device comprising:
a display panel;
a cover module covering a rear surface of the display panel; and
an adhesive member configured to bond the cover module to the display panel,
wherein the adhesive member comprises:
a first adhesive layer attached to the rear surface of the display panel;
a first film attached to the first adhesive layer;
an auxiliary adhesive layer attached to the first film;
a base layer attached to the auxiliary adhesive layer;
a second film attached to the base layer; and
a second adhesive layer having one side attached to the second film and the other side attached to the cover module.

2. The display device according to claim 1, wherein the cover module comprises:
a cover body located behind the display panel; and
a cover circumference portion protruding forward from a circumference of the cover body, surrounding an outer circumference of the display panel, and spaced apart from the outer circumference of the display panel to define a predetermined gap.

3. The display device according to claim 2, wherein the cover module further comprises a heat dissipation plate disposed between the cover body and the display panel, and
wherein the second adhesive layer is attached to the heat dissipation plate.

4. The display device according to claim 3, wherein the base layer is configured to be cut by a wire entered between the display panel and the heat dissipation panel through the gap.

5. The display device according to claim 1, wherein the adhesive member is provided in plurality, and
wherein a length corresponding to a thickness of the adhesive member is shorter than a length corresponding to a minimum distance between one adhesive member and another adhesive member adjacent to the one adhesive member.

6. The display device according to claim 1, wherein the base layer is located between the first adhesive layer and the second adhesive layer and has a thickness greater than that of each of the first adhesive layer and the second adhesive layer.

7. The display device according to claim 3, further comprising an electrical component provided on the cover body and having an opening communicating with a lower space of the heat dissipation plate.

8. The display device according to claim 7, wherein the opening is located in a central portion of the cover body with respect to a left-and-right direction.

9. The display device according to claim 1, wherein a material of the base layer is a polyurethane foam.

10. The display device according to claim 1, wherein a material of the first film is different from a material of the second film.

11. The display device according to claim 7, further comprising an auxiliary adhesive member configured to bond the display panel to the cover body,
wherein the opening is located above the auxiliary adhesive member.

12. The display device according to claim 7, wherein a burr formed around the heat dissipation plate faces the cover body.

13. The display device according to claim 7, wherein an edge of the opening is formed to be round.

14. A display device separation system comprising:
a display panel;
a cover module covering a rear surface of the display panel and having an opening;
an adhesive member located between the display panel and the cover module to bond the display panel to the cover module;
a wire configured to cut the adhesive member so that the display panel and the cover module are separated; and
an electromotive jig configured to wind the wire,
wherein, in a state in which the wire is located between the display panel and the cover module along the circumference of the display panel, passes through the opening, and is connected to the electromotive jig, the adhesive member is cut while the wire is wound around the electromotive jig by the rotation of the electromotive jig.

15. The display device separation system according to claim 14, further comprising a guide jig having a through hole through which the wire passes, the guide jig being seated on the rear surface of the cover module,
wherein the through hole corresponds to the opening.

16. The display device separation system according to claim 14, further comprising a fixing portion to which one end of the wire is fixed,
wherein the other end of the wire is connected to the electromotive jig.

17. The display device separation system according to claim 14, wherein the cover module comprises:
a cover body located behind the display panel; and
a cover circumference portion protruding forward from a circumference of the cover body, surrounding an outer circumference of the display panel, and spaced apart from the outer circumference of the display panel to define a predetermined gap, and
wherein the wire is inserted between the display panel and the cover body through the gap.

18. The display device separation system according to claim 17, wherein the cover module further comprises a heat dissipation plate disposed between the cover body and the display panel and having a front surface to which the adhesive member is attached, and
wherein the wire penetrates between the display panel and the heat dissipation plate and cuts the adhesive member.

19. The display device separation system according to claim 14, wherein a thickness of the wire is less than a thickness of the adhesive member.

20. The display device separation system according to claim 14, wherein the opening is located in a central portion of the cover module with respect to a left-and-right direction, and the guide jig is seated in a central portion of the rear surface of the cover module so as to correspond to the opening.
